(19) United States
(12) Patent Application Publication
(10) Pub. No.: US 2015/0060766 A1
(43) Pub. Date: Mar. 5, 2015

(54) TUNNELING FIELD EFFECT TRANSISTORS

(71) Applicant: SAMSUNG ELECTRONICS CO., LTD., Suwon-si (KR)

(72) Inventor: Ji-hyun HUR, Hwaseong-si (KR)

(21) Appl. No.: 14/471,799

(22) Filed: Aug. 28, 2014

(30) Foreign Application Priority Data
Aug. 30, 2013 (KR) 10-2013-0104400

(51) Int. Cl. H01L 29/775; H01L 29/20

(52) U.S. Cl. CPC H01L 29/775; H01L 29/20
USPC 257/24

(57) ABSTRACT

In another embodiment, the tunneling field effect TFET includes a source electrode, a drain electrode, and a channel layer between the source electrode and the drain electrode. A first junction surface is between the source electrode and the channel layer, and a second junction surface is between the drain electrode and the channel layer. A gate is on the channel layer. The gate has first and second side surfaces. The first side surface is at the source electrode side and the second side surface is at the drain electrode side. The first side surface extends from the channel layer.

### CROSS-REFERENCE TO RELATED APPLICATIONS

This application claims the benefit of Korean Patent Application No. 10-2013-0104400, filed on Aug. 30, 2013, in the Korean Intellectual Property Office, the disclosure of which is incorporated herein in its entirety by reference.

### BACKGROUND

1. Field

The present disclosure relates to tunneling field effect transistors (TFETs).

2. Description of the Related Art

Semiconductor microprocessors and highly-integrated circuits are manufactured by integrating devices, such as metal oxide semiconductor field effect transistors (MOSFETs), on a semiconductor substrate. For example, complementary metal oxide semiconductor (CMOS) may be used as a basic device of an integrated circuit (IC). A silicon substrate is widely used as a material of a semiconductor substrate. A degree of integration and performance of a semiconductor microprocessor and a highly-integrated circuit can be enhanced by miniaturizing a transistor configuring CMOS. However, when CMOS is miniaturized, power consumption increases, and due to this, there is a limitation in miniaturizing CMOS. Recently, due to a limitation for miniaturization in MOSFETs, tunneling field effect transistors (TFETs) using a tunneling phenomenon are being developed.

### SUMMARY

At least one embodiment provides a TFET with a reduced subthreshold swing.

Additional aspects will be set forth in part in the description which follows and, in part, will be apparent from the description, or may be learned by practice of the presented embodiments.

In one embodiment, a tunneling field effect transistor (TFET) includes: a source electrode; a drain electrode separated from the source electrode; a channel layer between the source electrode and the drain electrode; and a gate electrode overlapping only a portion of the channel layer.

The gate electrode may include a first side surface at the source electrode side and a second side surface at the drain electrode side, the first side surface is disposed separated from a first junction surface between the source electrode and the channel layer.

A distance from a first plane including the first side surface to a second plane including the first junction surface between the source electrode and the channel layer may have a range of about 2 nm to about 5 nm.

The second side surface one of (1) extends from the drain electrode and (2) is aligned with, a second junction surface between the channel layer and the drain electrode.

The source electrode, the channel layer, the drain electrode, and the gate electrode may have a planar structure.

The TFET may further include a substrate, and wherein the source electrode, the channel layer, and the drain electrode may be arranged in a width direction on the substrate.

The source electrode, the channel layer, the drain electrode, and the gate electrode may have a nanowire structure.

The gate electrode may have at least a partial cylindrical shape at least partially surrounding a partial circumference of the channel layer.

The TFET may further include a substrate, and wherein the source electrode, the channel layer, and the drain electrode structure extend from the substrate.

The substrate may be a silicon substrate, a sapphire substrate, or a III-V compound semiconductor substrate.

The source electrode, the channel layer, and the drain electrode may be formed of a IV group material or a III-V compound.

The source electrode and the drain electrode may be formed of an antimony (Sb)-based material, and the channel layer is formed of an arsenic (As)-based material.

The source electrode and the drain electrode may include at least one of InAs, InP, GaAs, GaN, AlSb, GaSb, InSb, AlGaAs, InGaAs, InGaN, AlGaN, GaNAs, GaAsSb, InGaSb, AlInSb, AlGaAs, InGaAs, InGaN, AlGaN, GaNAs, InAsSb, GaAsSb, InGaSb, and AlInS.

The TFET may further include a gate insulating layer disposed between the channel layer and the gate electrode.

The gate insulating layer may include silicon oxide, hafnium oxide, zirconium oxide, or tantalum oxide.

In another embodiment, the tunneling field effect TFET includes a source electrode, a drain electrode, and a channel layer between the source electrode and the drain electrode. A first junction surface is between the source electrode and the channel layer, and a second junction surface is between the drain electrode and the channel layer. A gate is on the channel layer. The gate has first and second side surfaces. The first side surface is at the source electrode side and the second side surface is at the drain electrode side. The first side surface extends from the channel layer.

In one embodiment, a plane including the first side surface is separated from a plane including the first junction surface by 2 nm to 5 nm.

In one embodiment, the second side surface extends from the drain electrode.

In one embodiment, the second side surface is aligned with the second junction surface.

In one embodiment, the TFET further includes a gate insulating layer between the gate and the channel layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view schematically illustrating a TFET according to an example embodiment;

FIG. 2 illustrates a TFET according to another embodiment;

FIG. 3 illustrates a TFET according to another embodiment; and

FIG. 4 shows the changes in current with respect to voltage in a TFET according to an embodiment.

FIGS. 5A-5D illustrate different structures of the TFET.

### DETAILED DESCRIPTION

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

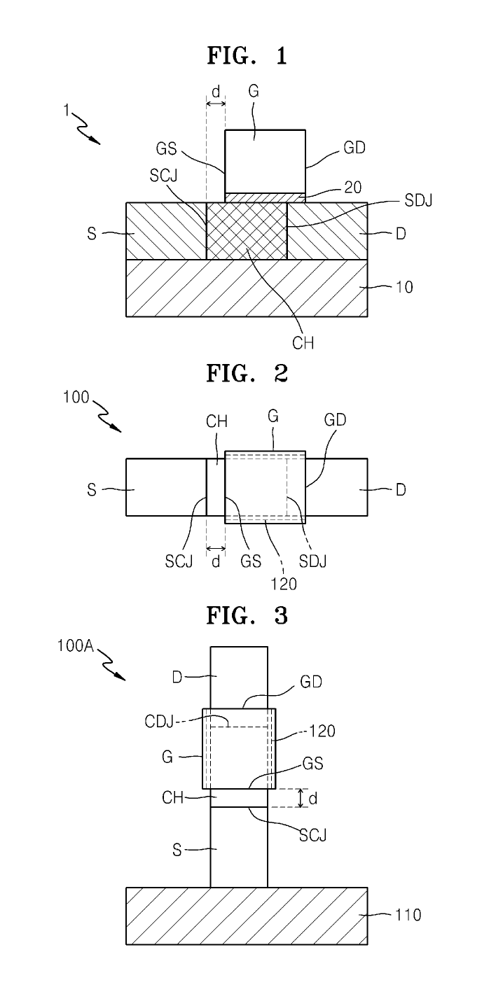

FIG. 1 is a cross-sectional view schematically illustrating a TFET 1 according to an embodiment. Referring to FIG. 1, the TFET 1 may include a substrate 10. A source electrode S and a drain electrode D are disposed on the substrate 10 separated from each other. A channel layer CH may be provided between the source electrode S and the drain electrode D. A gate electrode G may be disposed on the channel layer CH. The source electrode S, the channel layer CH, the drain electrode D, and the gate electrode G may have a planar structure.

A gate insulating layer 20 may be provided between the channel layer CH and the gate electrode G. When the gate electrode G is disposed on the channel layer CH, the gate electrode G may be disposed to overlap a portion of the channel layer CH. For example, a first portion of the gate electrode G may be disposed to overlap the channel layer CH, and a second portion may be disposed not to overlap the channel layer CH. For example, a first portion of the gate electrode G may be disposed to overlap the channel layer CH, and a second portion may be disposed to overlap the drain electrode D. For example, the gate electrode may overlap only a portion of the channel layer, not all over the channel. The gate electrode G may be relatively shifted toward the drain electrode D with respect to the source electrode S.

The gate electrode G may include a first side surface GS close to the source electrode S and a second side surface GD close to the drain electrode D. The gate electrode G may be disposed in order for the first side surface GS to extend from the channel layer CH. That is, the first side surface GS may be disposed to be shifted toward the drain electrode D with respect to a junction surface SCJ between the source electrode S and the channel layer CH. The second side surface GD may extend from the drain electrode D. Alternatively, the second side surface GD may be extend from the channel layer CH. Alternatively, the first side surface GS may aligned with the junction surface SCJ between the source electrode S and the channel layer CH. The gate electrode G may have the same length as that of the channel layer CH, or have a longer length than that of the channel layer CH. Alternatively, the gate electrode G may have a shorter length than that of the channel layer CH. Here, the length denotes an arrangement direction of the source electrode S, the channel layer CH, and the drain electrode D.

A distance d between a plane including the source channel junction surface SCJ and a plane including the first side surface GS may have, for example, a range of about 2 nm to about 5 nm. Thereby, a tunneling barrier may be heightened in an OFF state, thus decreasing an OFF leakage current. When the distance d between the source channel junction surface SCJ and the first side surface GS is not within the range, an ON current may increase, but an OFF current may also increase along with the on current. Due to this, a leakage current in the OFF state may increase. This will be described below.

The substrate 10 may be, for example, a silicon substrate or a sapphire substrate. The substrate 10 may be doped, or may not be doped. Alternatively, the substrate 10 may be a compound semiconductor substrate. A compound semiconductor may be, for example, a III-V compound semiconductor. The III-V compound semiconductor may be one of a semiconductor consisting of two elements, a semiconductor consisting of three elements, a semiconductor consisting of four elements, and a semiconductor consisting of more elements than four. A binary compound may include, for example, InAs, InP, GaAs, GaN, AlSb, GaSb, or InSb. A ternary compound may include, for example, AlGaAs, InGaAs, InGaN, AlGaN, GaNAs, GaAsSb, InGaSb, or AlInSb. A quaternary compound may include, for example, AlGaAs, InGaAs, InGaN, AlGaN, GaNAs, InAsSb, GaAsSb, InGaSb, and AlInSb.

The source electrode S, the channel layer CH, and the drain electrode D may include, for example, a group IV material such as silicon (Si) or germanium (Ge). Alternatively, the source electrode S, the channel layer CH, and the drain electrode D may be formed of, for example, a III-V compound. The III-V compound may be one of a semiconductor consisting of two elements, a semiconductor consisting of three elements, a semiconductor consisting of four elements, and a semiconductor consisting of more elements than that. A binary compound may include, for example, InAs, InP, GaAs, GaN, AlSb, GaSb, or InSb. A ternary compound may include, for example, AlGaAs, InGaAs, InGaN, AlGaN, GaNAs, GaAsSb, InGaSb, or AlInSb. A quaternary compound may include, for example, AlGaAs, InGaAs, InGaN, AlGaN, GaNAs, InAsSb, GaAsSb, InGaSb, and AlInSb.

For example, the source electrode S and the drain electrode D may be formed of an antimony (Sb)-based material, and the channel layer CH may be formed of an arsenic (As)-based material. The source electrode S (the drain electrode D) and the channel layer CH may be formed of GaSb—In(Ga)As or GaAlSb—In(Ga)As. The source electrode S and the drain electrode D may be respectively formed as opposite conductive types.

The source electrode S and the drain electrode D may be doped, or may not be doped. For example, the source electrode S and the drain electrode D may be doped as an n type or a p type. A dopant of the source electrode S may be changed according to a material of the source electrode S, and a dopant of the drain electrode D may be changed according to a material of the drain electrode D. When the source electrode S and the drain electrode D are formed of a III-V compound, the dopant of each of the source electrode S and the drain electrode D may be selected from among group IV elements including silicon (Si), germanium (Ge), and carbon (C). When the source electrode S and the drain electrode D are formed of a material including Si or Ge, the dopant of the drain electrode D may be, for example, an n-type dopant such as phosphorus (P), arsenic (As), or antimony (Sb), and the dopant of the source electrode S may be, for example, a p-type dopant such as boron (B) or indium (In). However, the dopants are not limited thereto. The channel layer CH, for example, may be intrinsic without being doped as a p type or an n type. Alternatively, the channel layer CH may be doped as a p type or an n type.

The gate insulating layer 20 is provided under the gate electrode G, and may overlap a portion of the channel layer CH like the gate electrode G. The gate insulating layer 20 may insulate the gate electrode G from the channel layer CH and the drain electrode D. The gate insulating layer 20 may include oxide or metal oxide. For example, the gate insulating layer 20 may include silicon oxide, hafnium oxide, zirconium oxide, or tantalum oxide. Alternatively, the gate insulating layer 20 may be formed in a multi-layer structure including oxide and nitride. For example, the gate insulating layer 20 may include at least one selected from the group consisting of HfO₂, Al₂O₃, La₂O₃, ZrO₂, HfSiO, HfSiO, HfLaO, LaAlO, and SrTiO.

The gate electrode G may be formed of metal.

The TFET 1 of FIG. 1 may be a planar transistor.

FIG. 2 illustrates a nanowire TFET 100 according to another embodiment. Referring to FIG. 2, the TFET 100 includes a source electrode S, a drain electrode D, and a channel layer CH between the source electrode S and the drain electrode D. The source electrode S, the channel layer CH, and the drain electrode D may have a nanowire structure (e.g., cylindrical with a diameter on the order of nano meters, and a greater length than width). A gate electrode G may be provided to overlap at least one portion of the channel layer CH. The gate electrode G may have a hollow cylindrical shape (or partial hollow cylindrical shape) surrounding (or partially surrounding) a circumference of the channel layer CH. A gate insulating layer 120 may be provided between the gate electrode G and the channel layer CH. The gate insulating layer 120 may have the same length as that of the gate electrode G. The gate insulating layer 120 may be the same as the gate insulating layer 20 described above with reference to FIG. 1, and thus, its detailed description is not provided.

The gate electrode G may include a first side surface GS at the source electrode S side and a second side surface GD at the drain electrode D side. The first side surface GS of the gate electrode G may extend from the channel layer CH. The first side surface GS may be relatively shifted toward the drain electrode D with respect to a junction surface SCJ between the source electrode S and the channel layer CH. A distance d from a plane including the first side surface GS to a plane including the junction surface (a source channel junction surface) SCJ between the source electrode S and the channel layer CH may have, for example, a range of about 2 nm to about 5 nm. Thereby, a tunneling barrier may be heightened in an OFF state, thus decreasing an OFF leakage current. When the distance d is not within this range, an ON current may increase, but an OFF current may also increase along with the ON current. Due to this, a leakage current in the OFF state may increase.

The second side surface GD may extend from the drain electrode D. Alternatively, the second side surface GD may be aligned with a junction surface SDJ between the channel layer CH and the drain electrode D, or may extend from the channel layer CH.

FIG. 3 illustrates a modification example of the nanowire type of TFET of FIG. 2. A TFET 100A illustrated in FIG. 3 has a structure in which a nanowire is vertically disposed relative to a substrate 300.

Referring to FIG. 3, the TFET 100A includes a substrate 110, a source electrode S on the substrate 110, a channel layer CH on the source electrode S, and a drain electrode D on the channel layer CH. The source electrode S, the channel layer CH, and the drain electrode D may have a nanowire structure. A gate electrode G may be provided to overlap a portion of the channel layer CH. The gate electrode G may have a cylindrical shape surrounding a circumference of the channel layer CH. A gate insulating layer 120 may be provided between the gate electrode G and the channel layer CH. For example, the gate insulating layer 120 may be provided between the gate electrode G and the channel layer CH, and between the gate electrode and the drain electrode D.

The gate electrode G may include a first side surface GS at the source electrode S side and a second side surface GD at the drain electrode D side. The first side surface GS of the gate electrode G may extend from the channel layer CH. The first side surface GS may be relatively shifted toward the drain electrode D with respect to the source electrode S. A distance d from a plane including the first side surface GS to a plane including a junction surface (a source channel junction surface) SCJ between the source electrode S and the channel layer CH may have, for example, a range of about 2 nm to about 5 nm.

The substrate 110, source electrode S, channel layer CH, and drain electrode D of FIG. 3 are the same as those of FIG. 1, and thus, their detailed description is not provided.

Next, an operation of the TFET according to an embodiment will be described.

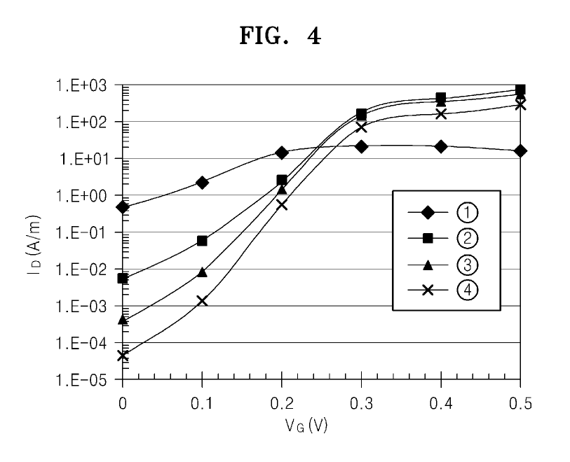

FIG. 4 shows the changes in current I_{D} with respect to voltage V_{G} in the TFET 100 of FIG. 2. The changes in current with respect to voltage were simulated for each position of the first side surface GS of the gate electrode D providing the distance d as shown in Table 1 below.

TABLE 1

| | | | |
|---|---|---|---|
| Position \textcircled{1} | Position \textcircled{2} | Position \textcircled{3} | Position \textcircled{4} |

| | | | |
|---|---|---|---|
| d = −5 nm | d = 0 nm | d = 2.5 nm | d = 5 nm |

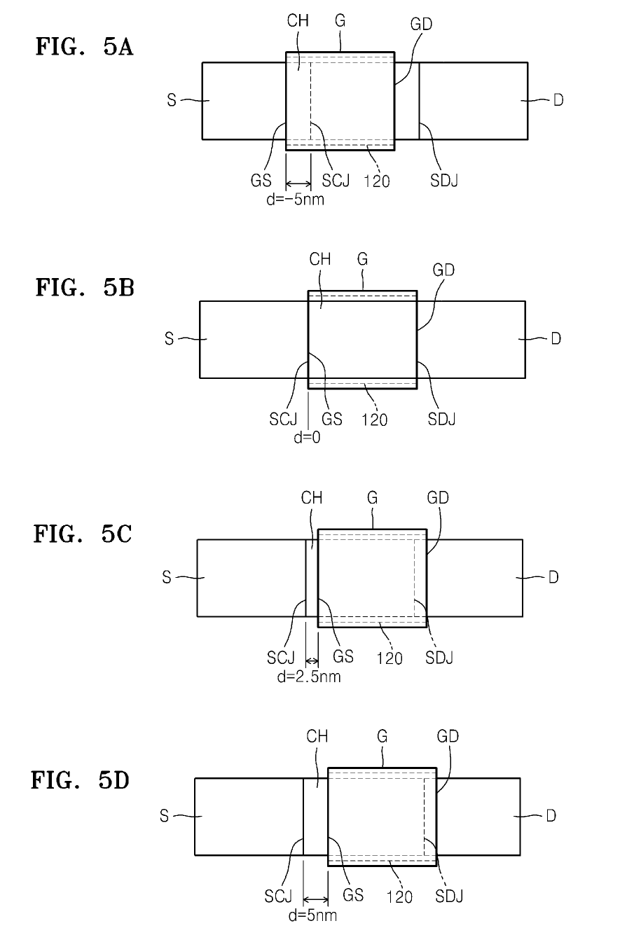

FIGS. 5A-5D illustrate the structure of the TFET 100 for positions 1-4, respectively, in Table 1.

For example, a length of the gate electrode G may be about 10 nm.

The following Table 2 shows a simulation result for each position.

TABLE 2

| | Position \textcircled{1} | Position \textcircled{2} | Position \textcircled{3} | Position \textcircled{4} |
|---|---|---|---|---|
| I_{ON} (μA/μm) | 2.3E+01 | 1.9E+02 | 1.6E+02 | 7.2E+01 |
| I_{OFF} (μA/μm) | 5.2E−01 | 5.8E−03 | 4.7E−04 | 4.6E−05 |
| I_{ON}/I_{OFF} | 4.3E+01 | 3.2E+04 | 3.4E+05 | 1.6E+06 |
| SS (mV/dec) | 124 | 61 | 45 | 38 |

Here, I_{ON} denotes an ON current, I_{OFF} denotes an OFF current, and SS denotes a subthreshold swing. The subthreshold swing denotes a degree of ease when a transistor current is changed to an OFF current, and may be one factor for determining a speed of a MOS apparatus.

According to Table 2, in the position \textcircled{1}, since an ON current is low but an OFF current is high, I_{ON}/I_{OFF} is small. In the position \textcircled{3} and the position \textcircled{4}, I_{ON}/I_{OFF} is large, and the subthreshold swing is small. The distance d from the first side surface GS to the junction surface (the source channel junction surface) SCJ between the source electrode S and the channel layer CH may have, for example, a range of about 2 nm to about 5 nm. Therefore, I_{ON}/I_{OFF} may increase, and the subthreshold swing may decrease. Accordingly, an OFF leakage current can be reduced, and moreover, power consumption can decrease.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A tunneling field effect transistor (TFET) comprising:
a source electrode;
a drain electrode separated from the source electrode;
a channel layer between the source electrode and the drain electrode; and
a gate electrode overlapping a portion of the channel layer.

2. The TFET of claim 1, wherein the gate electrode comprises a first side surface at the source electrode side and a second side surface at the drain electrode side, the first side surface is disposed separated from a first junction surface between the source electrode and the channel layer.

3. The TFET of claim 2, wherein a distance from a first plane including the first side surface to a second plane including the first junction surface between the source electrode and the channel layer has a range of about 2 nm to about 5 nm.

4. The TFET of claim 2, wherein the second side surface extends from the drain electrode or is aligned with a second junction surface between the channel layer and the drain electrode.

5. The TFET of claim 1, wherein the source electrode, the channel layer, the drain electrode, and the gate electrode have a planar structure.

6. The TFET of claim 5, further comprising:
a substrate; and
wherein the source electrode, the channel layer, and the drain electrode are arranged in a width direction on the substrate.

7. The TFET of claim 1, wherein the source electrode, the channel layer, the drain electrode, and the gate electrode have a nanowire structure.

8. The TFET of claim 7, wherein the gate electrode has a at least a partial cylindrical shape at least partially surrounding a circumference of the channel layer.

9. The TFET of claim 8, further comprising:
a substrate; and
wherein the source electrode, the channel layer, and the drain electrode form a structure extending from the substrate.

10. The TFET of claim 9, wherein the substrate is a silicon substrate, a sapphire substrate, or a III-V compound semiconductor substrate.

11. The TFET of claim 1, wherein the source electrode, the channel layer, and the drain electrode are formed of a IV group material or a III-V compound.

12. The TFET of claim 11, wherein the source electrode and the drain electrode are formed of an antimony (Sb)-based material, and the channel layer is formed of an arsenic (As)-based material.

13. The TFET of claim 11, wherein the source electrode and the drain electrode comprise at least one of InAs, InP, GaAs, GaN, AlSb, GaSb, InSb, AlGaAs, InGaAs, InGaN, AlGaN, GaNAs, GaAsSb, InGaSb, AlInSb, AlGaAs, InGaAs, InGaN, AlGaN, GaNAs, InAsSb, GaAsSb, InGaSb, and AlInS.

14. The TFET of claim 1, further comprising:
a gate insulating layer disposed between the channel layer and the gate electrode.

15. The TFET of claim 14, wherein the gate insulating layer includes silicon oxide, hafnium oxide, zirconium oxide, or tantalum oxide.

16. A tunneling field effect (TFET) transistor, comprising:
a source electrode;
a drain electrode;
a channel layer between the source electrode and the drain electrode, a first junction surface being between the source electrode and the channel layer, and a second junction surface being between the drain electrode and the channel layer; and
a gate on the channel layer, the gate having first and second side surfaces, the first side surface at the source electrode side and the second side surface at the drain electrode side, the first side surface extending from the channel layer.

17. The TFET of claim 16, wherein a first plane including the first side surface is separated from a second plane including the first junction surface by 2 nm to 5 nm.

18. The TFET of claim 17, wherein the second side surface extends from the drain electrode.

19. The TFET of claim 17, wherein the second side surface is aligned with the second junction surface.

20. The TFET of claim 2, further comprising:
a gate insulating layer between the gate and the channel layer.

21. The TFET of claim 2, wherein the first side surface is disposed to be shifted toward the drain electrode with respect to the first junction surface.
